(19) United States
(12) Patent Application Publication
(10) Pub. No.: US 2026/0364783 A1
(43) Pub. Date: Nov. 19, 2026

(54) SUBSTRATE PROCESSING APPARATUS

(71) Applicant: Brooks Automation US, LLC, Chelmsford, MA (US)

(72) Inventors: Matthew J. McLELLAN, Chelmsford, MA (US); Robert T. CAVENEY, Windham, NH (US)

(21) Appl. No.: 19/515,685

(22) PCT Filed: Sep. 3, 2024
(86) PCT No.: PCT/US2024/045027

§ 371 Date: Mar. 2, 2026

Related U.S. Application Data
(60) Provisional application No. 63/580,157, filed on Sep. 1, 2023.

(51) Int. Cl. B25J 9/04; B25J 9/12; B25J 11/00; B25J 15/00

(52) U.S. Cl. CPC B25J 9/043; B25J 9/126; B25J 11/0095; B25J 15/0014

(57) ABSTRACT

A substrate transport apparatus includes a frame, a first SCARA arm coupled to the frame at a shoulder axis of rotation that is fixed relative to the frame, a second SCARA arm coupled to the frame at the shoulder axis of rotation so that rotation of the first SCARA arm and the second SCARA arm about the shoulder axis of rotation is substantially coincident, and a five motor drive section with five independent motors configured to independently extend and rotate each of the first SCARA arm and the second SCARA arm. A first motor of the five independent motors is operably coupled to each first upper arm of both the first SCARA arm and the second SCARA arm so that the first motor is a common motor to both first upper arms respectively of both the first SCARA arm and the second SCARA arm.

### CROSS-REFERENCE TO RELATED APPLICATION(S)

This application is a National Stage of International Application No. PCT/US2024/045027, having an International Filing Date of Sep. 3, 2024, which designated the United States of America, and which International Application was published under PCT Article 21(2) as WO Publication No. WO 2025/050119, which claims priority under 35 USC § 119(e) of U.S. Provisional Patent Application No. 63/580,157, filed on Sep. 1, 2023, the disclosures of which are hereby incorporated by reference in their entireties.

### BACKGROUND

### 1. Field

The exemplary embodiments generally relate to substrate processing tools, and more particularly, to substrate transport apparatus.

### 2. Brief Description of Related Developments

Customers continue to build systems with the configuration of having side-by-side process module or holding stations that require either individual process/service for one process side while also allowing the automation to be enabled to load both sides for parallel processing on the side-by-station. In most cases, these cluster tool chambers are configured in a square or pentagon shaped chamber with sufficient size to enable each facet to have a pair of process modules side-by-side. These process modules are usually configured so that they share process gas facilities but can be either operational at the same time or independently shut down for either sequence matching or service.

Typically controlling the orientation of a substrate (e.g., notch location on a substrate) is not controlled during substrate transport. Such orientation control is not generally possible with a three-axis dual SCARA arm, as the wrist axes are not controllable as the wrist axes re typically slaved to the forearms. When multiple robots in the same system handle wafers (ex. ATM and VAC robots) with varying handoff angles, the substrate orientation will rotate as it passes through the tool.

Accordingly, the present disclosure addresses a number of those issues.

### BRIEF DESCRIPTION OF THE DRAWINGS

The foregoing aspects and other features of the disclosed embodiment are explained in the following description, taken in connection with the accompanying drawings, wherein:

FIG. 1 is a robot assembly in accordance with the present disclosure;

FIG. 2 is a kinematic chain illustrating a robot assembly of in accordance with the present disclosure;

FIG. 3 is a kinematic chain illustrating a robot assembly of in accordance with the present disclosure;

FIG. 4 is a drive section for a robot assembly in accordance with the present disclosure;

FIG. 5 is an arm configuration of a robot assembly in accordance with the present disclosure;

FIGS. 6-10 illustrate exemplary movements of the robot assembly of FIG. 5 in accordance with the present disclosure;

FIG. 11 is an exemplary substrate handoff with radial arm extension;

FIG. 12 is an exemplary substrate handoff in accordance with the present disclosure;

FIG. 13 is an arm configuration of a robot assembly in accordance with the present disclosure;

FIG. 14 is a drive section for a robot assembly in accordance with the present disclosure;

FIGS. 15 and 16 illustrate a robot assembly in accordance with the present disclosure;

FIGS. 17-19 illustrate exemplary movements of the robot assembly of FIGS. 15 and 16 in accordance with the present disclosure;

FIGS. 20-22 illustrate a robot assembly in accordance with the present disclosure; and

FIG. 23 is a flow diagram of an exemplary method in accordance with the present disclosure.

### DETAILED DESCRIPTION

The following detailed description is meant to assist the understanding of one skilled in the art, and is not intended in any way to unduly limit claims connected or related to the present disclosure.

The following detailed description references various figures, where like reference numbers refer to like components and features across various figures, whether specific figures are referenced, or not.

The word “each” as used herein refers to a single object (i.e., the object) in the case of a single object or each object in the case of multiple objects. The words “a,” “an,” and “the” as used herein are inclusive of “at least one” and “one or more” so as not to limit the object being referred to as being in its “singular” form.

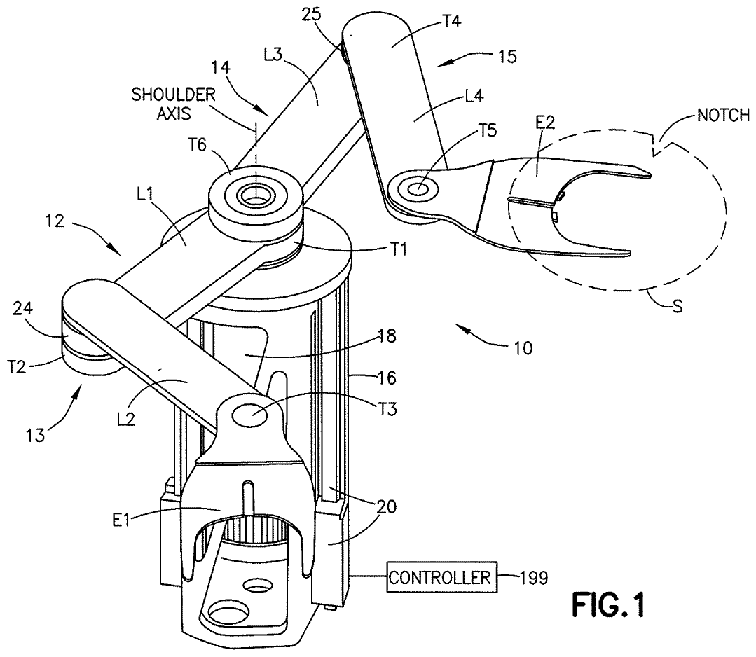

FIG. 1 illustrates an exemplary dual arm SCARA transport apparatus (also referred to herein as a robot assembly or substrate transport apparatus) 10 in accordance with the present disclosure. Although the present disclosure will be described with reference to the drawings, it should be understood that the present disclosure can be embodied in many forms. In addition, any suitable size, shape or type of elements or materials could be used.

The present disclosure provides for substrate processing automation to independently address process modules on the opposing sides of the chamber or substrate holding/interface stations. The present disclosure provides for controlling the orientation (i.e., of the notch location of the substrate) and position of a substrate S (also referred to herein as a wafer). The notch of the substrate S indicates a predetermined alignment for processes performed on the substrate S, where the substrate S is to be oriented with substantially the same orientation from process to process. In the present disclosure, at least three axes of control are provided for each substrate S held and transported by the dual arm robot assembly 10. The three axes of control per substrate S may provide for maintaining substrate orientation (during process tool operation) where multiple robots in the same system hand off the substrate from one robot to another (e.g., such as between an atmospheric robot and a vacuum robot, between two atmospheric robots, between two vacuum robots, etc.) with varying handoff angles.

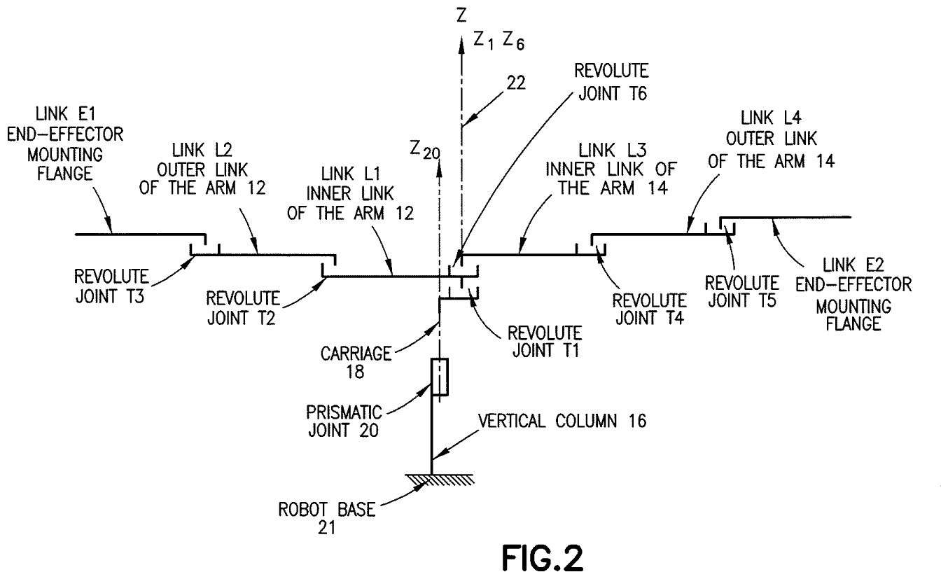

The robot assembly 10 illustrated in FIG. 1 may include two SCARA arms 12, 14 (e.g., the SCARA arm 12 may be referred to as a first SCARA arm 12 and the SCARA arm 14 may be referred to as a second SCARA arm 14) that share a common prismatic joint 20/carriage 18 linkage. The common carriage link 18 is located within the envelope of a column or frame 16. Each arm further includes a limb 13, 15 that is movable in a horizontal plane and mounted atop the common carriage link 18. Referring to the kinematic chain illustrated schematically in FIG. 2, four joint/link pairs are evident for each arm, and the arms may be coupled to a prismatic joint 20/carriage 18 for movement in the Z direction. Referring to arm 12, these pairs are prismatic joint 20/carriage 18, revolute joint or shoulder axis T1/inner link (also referred to as an upper arm link) L1, revolute joint or elbow axis T2/outer link (also referred to as a forearm link) L2, and revolute joint or wrist axis T3/link (also referred to as an end effector or substrate holder) E1. Referring to arm 14, these pairs are prismatic joint 20/carriage 18, revolute joint or shoulder axis T6/inner link (also referred to as an upper arm link) L3, revolute joint or elbow axis T4/outer link L4 (also referred to as a forearm link), and revolute joint or wrist axis T5/link (also referred to as an end effector or substrate holder) E2. Thus, the limbs 13, 15 are mounted for revolution about the axis of revolute joints T1 and T6 respectively. As a result of this arrangement, a Z-axis 22 positioned along the axis of the joints T1 and T6 can be located and described as a common axis 22 of the carriage 18. The limbs of both arms are able to extend and retract in a radial direction independently of each other.

The first SCARA arm 12 is coupled to the frame 16 at a shoulder axis of rotation that is fixed relative to the frame 16. The first SCARA arm 12 has a first upper arm L1, a first forearm L2, and at least one substrate holder E1 serially and rotatably coupled to each other. The second SCARA arm 14 is coupled to the frame 16 at the shoulder axis of rotation so that rotation of the first SCARA arm 12 and the second SCARA arm 14 about the shoulder axis of rotation is substantially coincident. The second SCARA arm 14 has a second upper arm L3, a second forearm L4, and at least one substrate holder E2 serially and rotatably coupled to each other. The drive section 220C is connected to the frame 16 and coupled to the first SCARA arm 12 and the second SCARA arm 14.

Each distal-most link E1, E2 may support a tool. While each SCARA arm 12, 14 is illustrated as having one link E1, E2, one or more of the SCARA arms may have more than one link coupled to the respective forearm link L2, L4 at the respective revolute joint. In the semiconductor industry, these links are referred to as end effector mounting flanges, and are connected to the outer links of the manipulator via the wrist rotary joints T3 and T5. The tools supported by the end effector mounting flanges are often called end effectors. The end effector mounting flanges may be identical or different, depending on the application.

Motion of a particular joint causes the links attached to that joint to move. Upon actuation, each limb is able to move in a distal or a proximal direction to provide straight-line radial translation of the end effector, maintaining a projection of the axis of the end effector aligned to intersect the common axis 22 of the carriage 18, about which the links L1 and L3, connected via the rotary joints T1 and T2, rotate. For purposes of describing the present invention, the term “distal” is a relative term that refers to a direction generally away from the common axis 22. The term “proximal” is a relative term that refers to a direction generally toward the common axis 22.

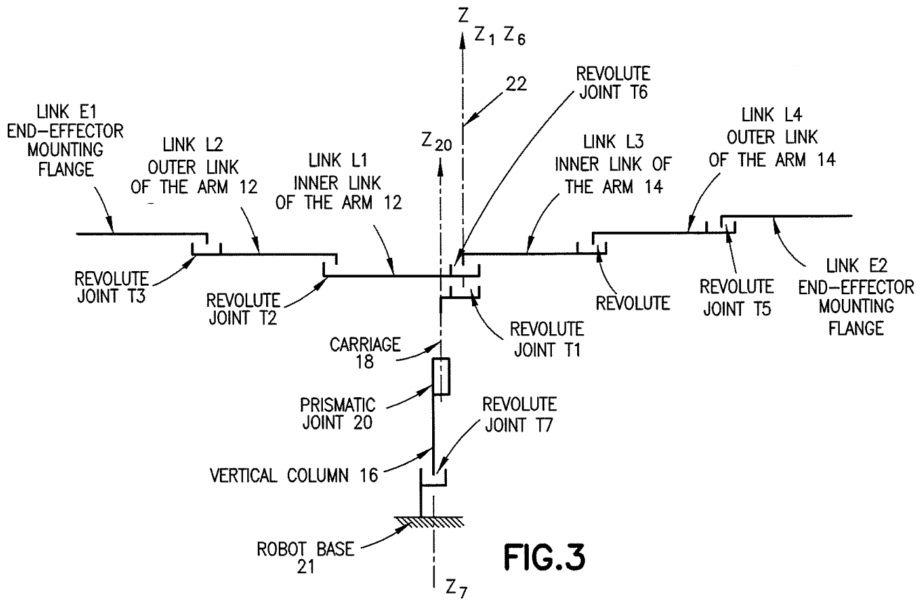

The carriage 18 is connected via the prismatic joint 20 to a vertical column 16 for vertical linear motion along the axis Z₂₀ of the vertical column 16. See FIG. 2. The axis Z₂₀ is parallel to the common axis 22 of the carriage 18, about which the links L1 and L3 rotate. The two limbs 13, 15 are supported by the carriage 18 on the column 16. The vertical column may also be mounted for rotation on a base 21 via a revolute joint T7, as indicated schematically in FIG. 3. The base may also be referred to a link L0. In this manner, the column allows for vertical movement of the arm assemblies and the carriage as a unit in the Z direction and, if the revolute joint T7 is present, the column may rotate about the axis of the joint T7 with respect to the robot's base 21 containing the joint's actuator.

As noted above, each inner link L1, L3 is attached to the carriage 18 via a proximal, or shoulder, rotary joint T1, T6. The shoulder joints T1, T6 of the two arms 12, 14 are co-linear on the common axis 22 of the carriage 18 and vertically offset, one above the other. The end effector mounting flanges E1, E2 move in horizontal planes that are parallel to each other, one horizontal plane may be substantially coincident or offset vertically from the other horizontal plane. The elbow joint of at least one arm, joint T2 of arm 12, may include a spacer 24 to space the outer link L2 from the inner link L1 by an amount sufficient to offset the two end effector mounting flanges E1, E2 vertically. In FIG. 1, in which the limbs are the same length, the joint T4 may also include a spacer 25 to space the outer link L4 from the inner link L3 by an amount sufficient to offset the two end effector mounting flanges E1 and E2 vertically. In this manner, the end effectors may not interfere with each other when the two arm assemblies are configured for moving independently with unrestricted rotation about the Z-axis.

The two SCARA arms 12, 14 are driven by, and the robot assembly 10 includes, what may be referred to as a five-axis drive system, where the two limbs 13, 15 of the robot assembly 10 are independently operable. In this context, it will be appreciated that the term “five-axis” refers to the system of revolute joint/link pairs that allow the motion of the limbs of the arms in a plane described by polar R-θ coordinates. For descriptive purposes only, the mechanism of the vertical displacement of the arm is not included in the term “five-axis.”

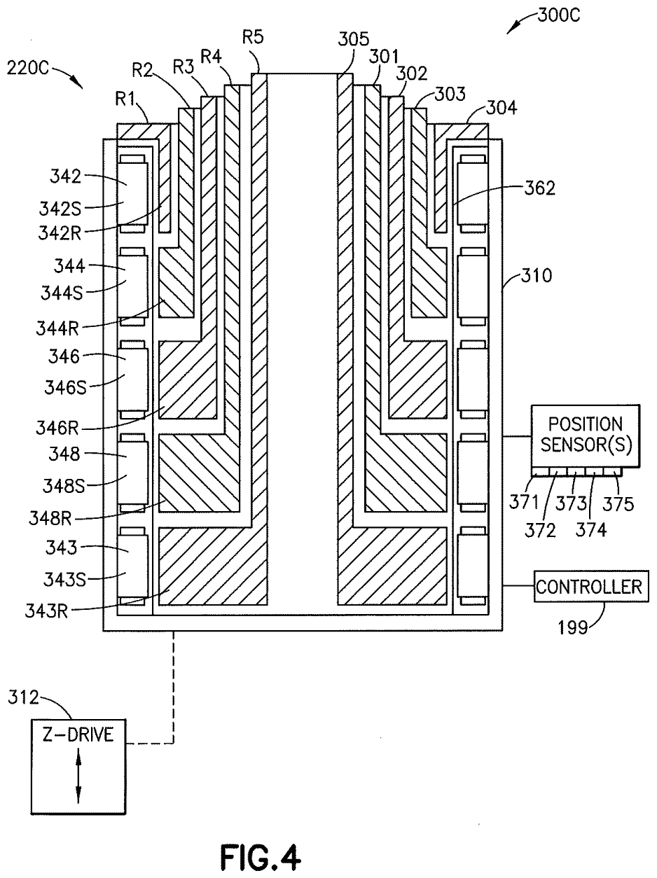

Referring to FIG. 4, the five-axis drive section 220C, is illustrated for exemplary purposes. The drive section 220C is connected to the frame 16 and is coupled to the first SCARA arm 12 and the second SCARA arm 14. The drive section 220C is a five motor drive section with five independent motors 342, 343, 344, 346, 348. The five independent motors 342, 343, 344, 346, 348 of the drive section 220C independently extend and rotate each of the first SCARA arm 12 and the second SCARA arm 14, so each of the first SCARA arm 12 and the second SCARA arm 14 extend independently from another of the first SCARA arm 12 and the second SCARA arm 14 and each at least one substrate holder E1, E2 respectively of the first SCARA arm 12 and the second SCARA arm 14 rotates independently of each other at least one substrate holder E1, E2 of the first SCARA arm 12 and the second SCARA arm 14.

A first motor 342 of the five independent motors is operably coupled to each first upper arm L1, L3 of both the first SCARA arm 12 and the second SCARA arm 14 so that the first motor 342 is a common motor to both first upper arms L1, L3 respectively of both the first SCARA arm 12 and the second SCARA arm 14.

A second independent motor 348 of the five independent motors 342, 343, 344, 346, 348, is operably coupled to the at least one substrate holder E1 of the first SCARA arm 12, so as to independently rotate the at least one substrate holder E1 about a first wrist axis T3 of the first SCARA arm 12 independent of each other at least one substrate holder E1, E2 of the first SCARA arm 12 and the second SCARA arm 14.

A third independent motor 343 of the five independent motors 342, 343, 344, 346, 348, is operably coupled to the at least one substrate holder E2 of the second SCARA arm 14, so as to independently rotate the at least one substrate holder E2 about a second wrist axis T5 of the second SCARA arm 14 independent of each other at least one substrate holder E1, E2 of the first SCARA arm 12 and the second SCARA arm 14.

A fourth independent motor 344 of the five independent motors 342, 343, 344, 346, 348, is operably coupled to the first forearm L2 of the first SCARA arm 12, so as to independently rotate the first forearm L2 about a first elbow axis T2 of the first SCARA arm 12 independent of each other arm link L1, L3, L4, and the at least one substrate holder E1, E2 of the first SCARA arm 12 and the second SCARA arm 14.

A fifth independent motor 346 of the five independent motors 342, 343, 344, 346, 348, is operably coupled to the second forearm L4 of the second SCARA arm 14, so as to independently rotate the second forearm L4 about a second elbow axis T4 of the second SCARA arm 14 independent of each other arm link L3, L1, L2 and the at least one substrate holder E1, E2 of the first SCARA arm 12 and the second SCARA arm 14.

The second independent motor 348 and the third independent motor 343 one or more of: orientate the at least one substrate holder E1, E2 respectively of the first SCARA arm 12 and the second SCARA arm 14 responsive to a predetermined orientation of a wafer S transported by the at least one substrate holder E1, E2 respectively of the first SCARA arm 12 and the second SCARA arm 14; rotate the at least one substrate holder E1, E2 respectively of the first SCARA arm 12 and the second SCARA arm 14 so as to effect a predetermined orientation of a wafer S transported by the at least one substrate holder E1, E2 respectively of the first SCARA arm 12 and the second SCARA arm 14; and orientate the at least one substrate holder E1, E2 respectively of the first SCARA arm 12 and the second SCARA arm 14 responsive to a predetermined orientation of a wafer S transported by another at least one substrate holder of another SCARA arm placing the wafer S for handoff to the first SCARA arm 12 or the second SCARA arm 14.

The drive section 220C includes a housing or frame 310, that is connected to the frame 16, for at least partially housing a quintuple-coaxial drive shaft assembly 300C having five drive shafts 301-305 and five motors 342, 344, 346, 348, 343 (e.g. a five-degree of freedom motor or five-axis motor/drive section). The drive section 220C may also include a Z-axis drive 312 configured to, e.g., raise and lower the arm (such as those described herein) of the robot assembly 10 for picking and placing substrates S; however, the substrate holding stations coupled to the transfer chamber in which the robot assembly 10 is at least partially located may include Z-axis drive(s) for lifting and lowering the substrates from and to the robot assembly 10 in lieu of or in addition to the Z-axis drive 312 of the drive section 220C.

The first motor 342 of the drive section 220C includes a stator 342S and a rotor 342R connected to the outer shaft 304 (e.g., the R1 axis of rotation). The second motor 344 includes a stator 344S and a rotor 344R connected to shaft 303 (e.g., the R2 axis of rotation). The third motor 346 includes a stator 346S and a rotor 346R connected to shaft 302 (e.g., the R3 axis of rotation). The fourth motor 348 includes a stator 348S and a rotor 348R connected to shaft 301 (e.g., the R4 axis of rotation). The fifth motor 343 includes a stator 343S and a rotor 343R connected to shaft 305 (e.g., the R5 axis of rotation. The five stators 342S, 344S, 346S, 348S, 343S are stationarily attached to the housing 310 at different vertical heights or locations within the housing. Each stator 342S, 344S, 346S, 348S, 343S generally comprises an electromagnetic coil. Each of the rotors 342R, 344R, 346R, 348R, 343R generally comprises permanent magnets, but may alternatively comprise a magnetic induction rotor that does not have permanent magnets. The motors 342, 344, 346, 348, 343 may be variable or switched reluctance motors such as those described in U.S. Pat. Nos. 10,348,172 and 9,948,155 and U.S. patent application Ser. No. 14/540,058 titled “Position Feedback for Sealed Environments” filed on Nov. 13, 2014, the disclosures of which are incorporated herein by reference in their entireties. The motors 342, 344, 346, 348, 343 may be harmonic drives such as those described in U.S. Pat. No. 9,656,386 the disclosure of which is incorporated herein by reference in its entirety. Where the robot assembly 10 is used in a sealed environment, such as for non-limiting exemplary purposes only, a vacuum environment, sleeves 362 may be located between the rotors 342R, 344R, 346R, 348R, 343R and the stators 342S, 344S, 346S, 348S, 343S so that the coaxial drive shaft assembly 300C is located in the sealed environment and the stators are located outside the sealed environment. It is noted the sleeves 362 need not be provided if the robot assembly 10 is only intended for use in an atmospheric environment, such as within an atmospheric section of any suitable substrate processing apparatus.

The shaft 305 extends from the fifth stator 343S and includes rotor 343R, which is substantially aligned with the stator 343S. The shaft 302 extends from the third stator 346S and includes rotor 346R, which is substantially aligned with the stator 346S. The shaft 301 extends from the fourth stator 348S and includes rotor 348R, which is substantially aligned with the stator 348S. The shaft 303 extends from the second stator 344S and includes the rotor 344R, which is substantially aligned with the stator 344S. The shaft 304 extends from the top or first stator 342S and includes rotor 342R, which is substantially aligned with the stator 342S. Various bearings (such as those described above) are provided about the shafts 301-305 and the housing 310 to allow each shaft 301-305 to be independently rotatable relative to each other and the housing 310. It is noted that each shaft may be provided with a position sensor 371-375. The position sensors 371-375 may be used to provide a signal to any suitable controller, such as controller 170, regarding the rotational position of a respective shaft 301-306 relative to each other and/or relative to the housing 310. The sensors 371-375 may be any suitable sensors, such as for non-limiting exemplary purposes, optical or induction sensors. The drive section 220C is configured to extend and retract at least one of the arms 12, 14 along a non-radial linear path or a radial linear path.

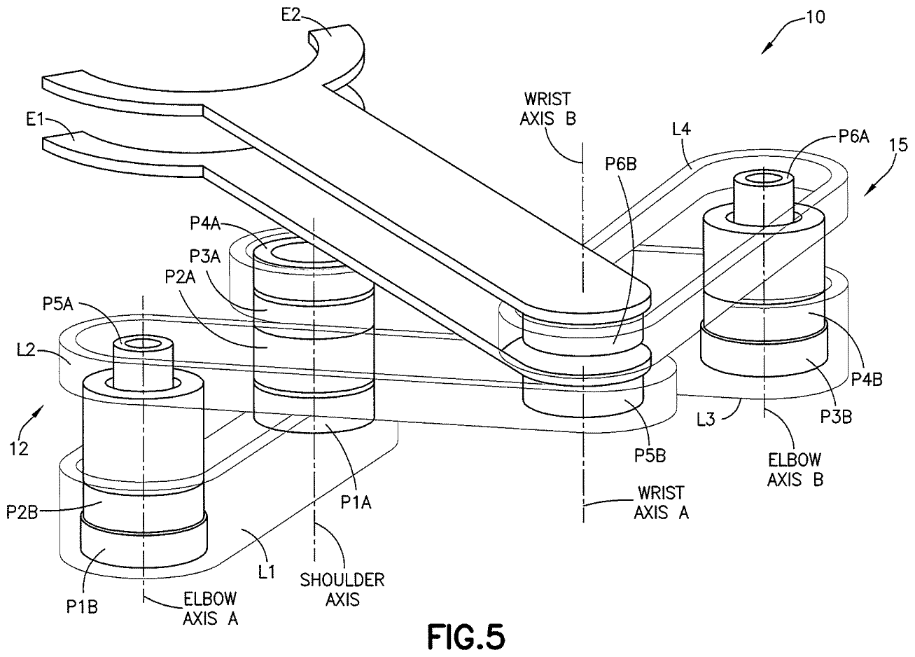

Referring to FIGS. 4 and 5, the R1 axis of rotation is coupled, in any suitable manner, to and drives rotation of the upper arm links L1, L3 about the shoulder axis (i.e., the R1 axis is common to and is shared by both upper arm links L1, L3 so that the upper arm links L1, L3 rotate as a unit about the shoulder axis). The R2 axis of rotation is coupled, in any suitable manner, to and drives rotation of the forearm link L2 about elbow axis A. The R4 axis of rotation is coupled, in any suitable manner, to and drives rotation of the end effector link E1 about wrist axis A. The R3 axis of rotation is coupled, in any suitable manner, to and drives rotation of the forearm link L4 about elbow axis B. The R5 axis of rotation is coupled, in any suitable manner, to and drives rotation of the end effector link E2 about wrist axis B. The coupling between the drive axes R1-R5 (where each drive axis R1-R5 is embodied in, or otherwise defined by, a respective drive shaft or drive member 301-305) and the respective arm links may be any suitable couplings such as band and pulley couplings (the pulleys of respective pulley pairs P1A-P1B, P2A-P2B, P3A, P3B, P4A-P4B, P5A-P5B, P6A-P6B are coupled to each other by opposing bands as is known-e.g., pulley P1A and P1B are coupled to each other by respective opposing bands, pulleys P2A and P2B are coupled to each other by respective opposing bands, etc.) such as those described in U.S. Pat. No. 9,623,555 issued on Apr. 18, 2017 and U.S. Pat. No. 7,891,935 issued on Feb. 22, 2011; and United States pre-grant publication number 2021/0257241 published on Aug. 19, 2021, the disclosure of which re incorporated herein by reference in their entireties. It is noted that the drive configuration and drive couplings described herein are exemplary only and the robot assembly 10 may be configured such that the axes R1-R5 are any combination of the above axes. In the figures, the pulley ratio in the forearm is 2:1 between the wrist pulleys P5B, P6B and elbow pulleys P5A, P6A, and a 1:1 ratio between the shoulder pulleys P1A-P4A and elbow pulleys P1B-P4B in the upper arms L1, L3, although, the pulley ratios may be any suitable ratios.

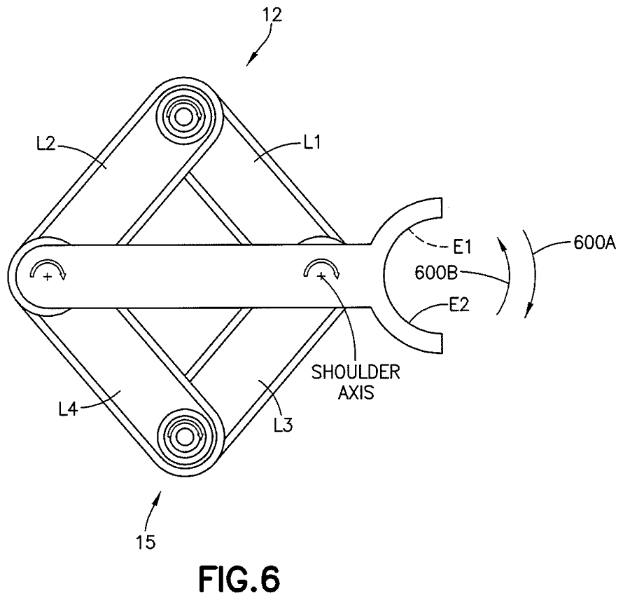

Referring to FIGS. 1-4, and 6, rotation of all axes R1-R5 as a unit and in the same direction (e.g., under control of any suitable controller 199) and speed will rotate the arms 12, 14 about the should axis, with end effectors remaining in the retracted position (as illustrated in FIG. 6), as a unit in one of directions 600A, 600B depending on the direction of rotation of the drive shafts 304-305.

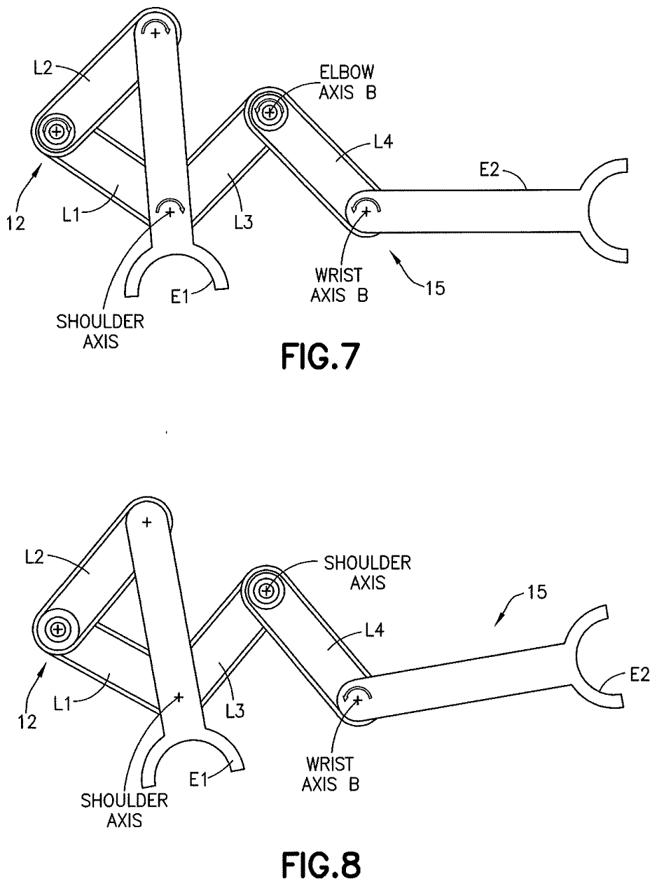

Referring to FIGS. 1-4, and 7, to extend the arm 12, the motors of the drive section 220C are controlled by controller 199 to Rotate axes R1, R4, R5, R3 clockwise (CW) and rotate R2 counter-clockwise (CCW). The rotations of the Axes R1-R5 are reversed to retract the arm 15. Here, the wrist axis A tracks radially with arm motion in the same manner as a slaved wrist configuration.

Referring to FIGS. 1-4, and 8, to rotate the end effector E1, the axes R1-R4 are held stationary and axis R4 is rotated, such as under control of controller 199, so that the end effector E1 is rotated about the wrist axis A.

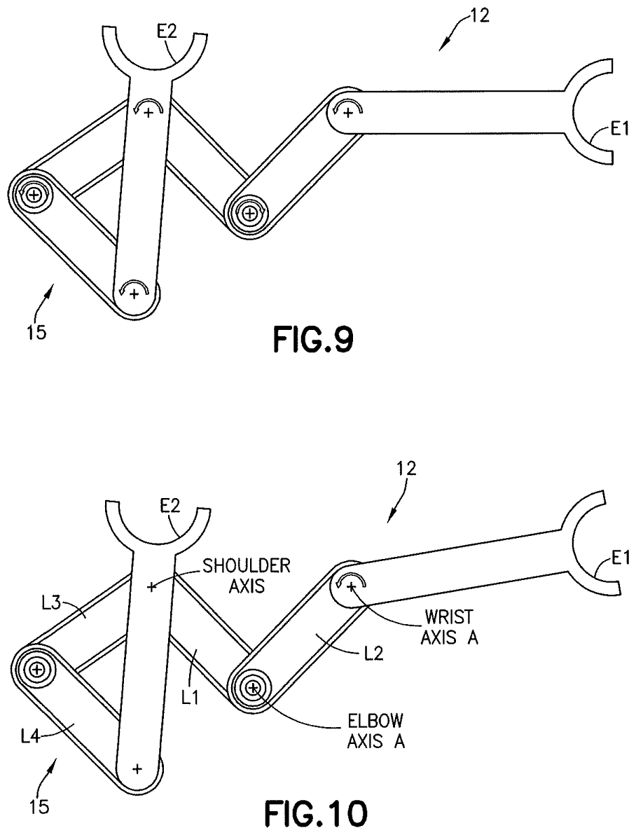

Referring to FIGS. 1-4, and 9, to extend the arm 15, the motors of the drive section 220C are controlled by controller 199 to Rotate axes R1, R4, R2, R5 counter-clockwise (CCW) and rotate R3 clockwise (CW). The rotations of the Axes R1-R5 are reversed to retract the arm 12. Here, the wrist axis A tracks radially with arm motion in the same manner as a slaved wrist configuration.

Referring to FIGS. 1-4, and 10, to rotate the end effector E2, the axes R1-R4 are held stationary and axis R5 is rotated, such as under control of controller 199, so that the end effector E2 is rotated about the wrist axis B.

The above examples illustrate a robot assembly 10 with a 2:1 pulley ratio between the wrist and elbow, although different pulley ratios between the wrist and elbow may be employed. This still allows independent control of the wrist axes, but the above control examples would be different. For example, a 1:1 ratio could also be used between the wrist and elbow, but then R4 would need to be held stationary (rather than rotating along with R1) in the example of arm 12 extension.

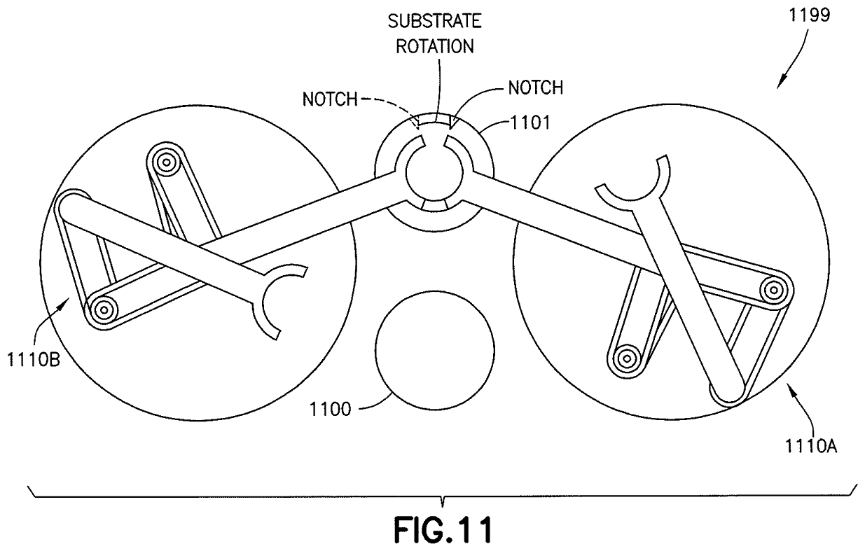

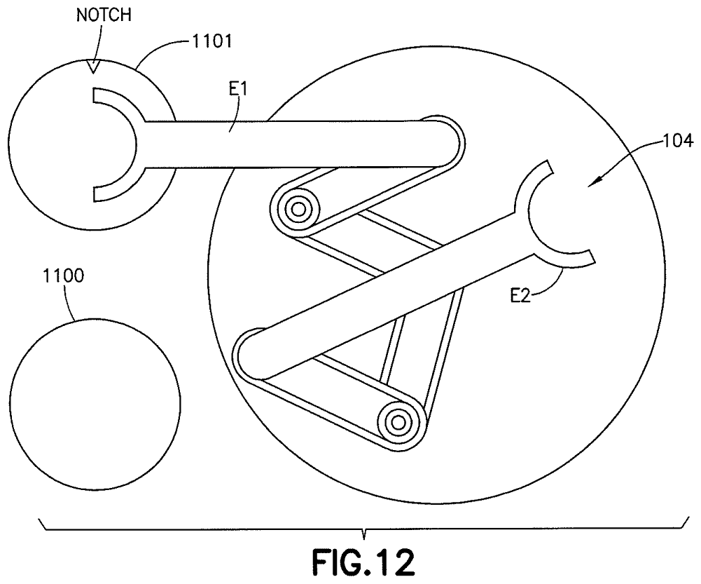

Referring to FIGS. 1-4, and 11, exemplary processing system layouts that includes two vacuum robots 1110A, 1110B are illustrated for exemplary purposes only (as noted above any combination of vacuum and atmospheric robots may be employed). Here, there is a pair of handoff stations 1100, 1101 between the two robots 10A, 10B to enable transport of substrates S within a processing tool 1199. If the robots 10A, 10B do not have an active wrist axis then there will be an angular offset in the substrate S position introduced because the robots 10A, 10B approach the handoff stations 1101 from different angles. Passing the substrate S between robots 10A, 10B through the handoff station 1100 would result in relative substrate rotation in the opposite direction. A similar relative substrate rotation can exist between a front-end robot and a vacuum robot when the front-end robot handoffs are orthogonal to the vertical plane and the vacuum robot handoffs are not. In the present disclosure, referring to FIG. 12, the active wrist robot 10A can access the same handoff stations 1100, 1101, but keep the end effector E1, E2 orthogonal to the plane between the two handoff stations 1100, 1101 such that no relative substrate S rotation occurs, no matter which handoff station 100, 1101 is employed.

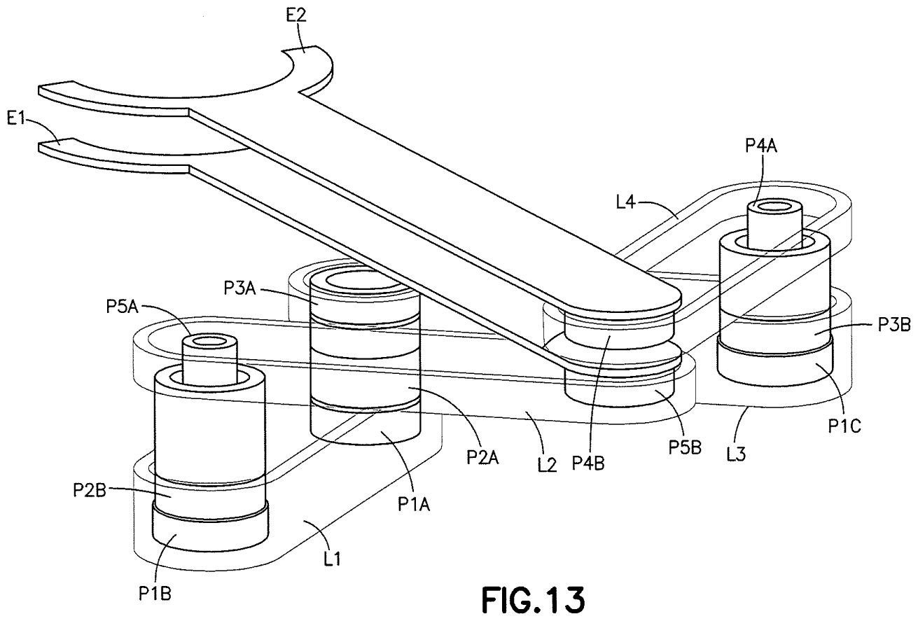

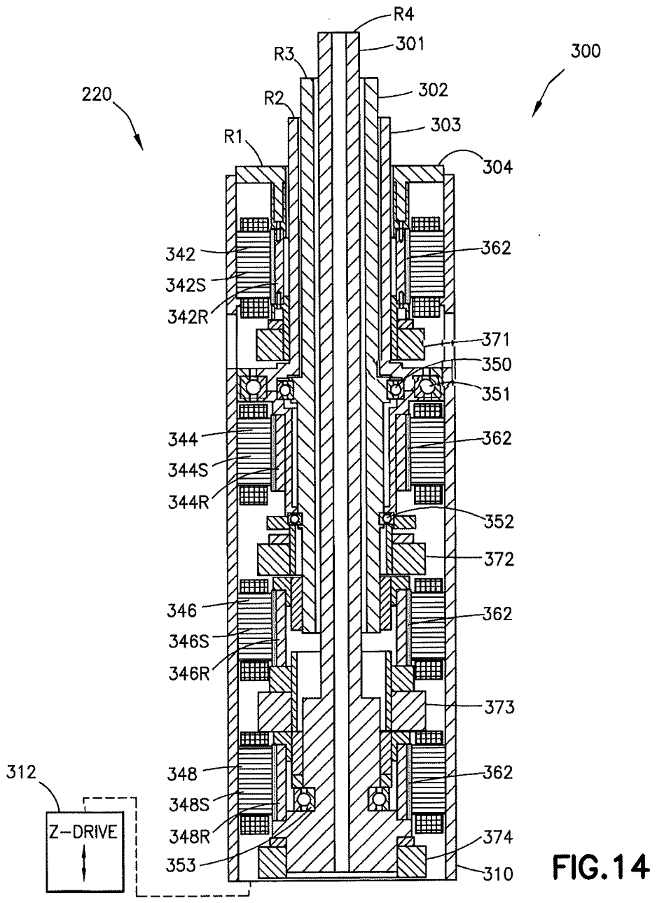

Referring to FIG. 13, an exemplary four-axis drive robot assembly 10A is illustrated. The robot assembly 10A is substantially similar to robot assembly 10 described above, however, the end effectors E1, E2 are driven by a common axis of a four-axis drive section 220, an example of which is illustrated in FIG. 14.

The drive section 220 may have a coaxial drive arrangement (similar to drive section 220C), although the drive section 220, 220C may have any suitable drive arrangement including but not limited to side-by-side motors, harmonic drives, switched or variable reluctance motors, etc. Suitable examples of drive section arrangements are described in U.S. Pat. Nos. 6,485,250; 5,720,590; 5,899,658; 5,813,823; 8,283,813; 8,918,203; and 9,186,799 , the disclosures of which are incorporated by reference herein in their entireties. The drive section 220 includes a housing 310 for at least partially housing a quad-coaxial drive shaft assembly 300 having four drive shafts 301-304 and four motors 342, 344, 346, 348 (e.g. a four-degree of freedom or four axis motor). The drive section 220 may also include a Z-axis drive 312 configured to, e.g., raise and lower the arms 12, 15 for picking and placing substrates S; however, the substrate processing stations coupled to the transfer chamber in which the arm 131 is located may include Z-axis drives for lifting and lowering the substrates from and to the arms 12, 15 in lieu of or in addition to the Z-axis drive 312 of the drive section 220.

Referring to FIG. 14, the drive section includes at least motors 342, 344, 346, 348. The first motor 342 of the drive section 220 includes a stator 342S and a rotor 342R connected to the outer shaft 304. The second motor 344 includes a stator 344S and a rotor 344R connected to shaft 303. The third motor 346 includes a stator 346S and a rotor 346R connected to shaft 302. The fourth motor 348 includes a stator 348S and a rotor 348R connected to the fourth or inner shaft 301. The four stators 342S, 344S, 346S, 348S are stationarily attached to the housing 310 at different vertical heights or locations within the housing. Each stator 342S, 344S, 346S, 348S generally comprises an electromagnetic coil. Each of the rotors 342R, 344R, 346R, 348R generally comprises permanent magnets, but may alternatively comprise a magnetic induction rotor that does not have permanent magnets. The motors 342, 344, 346, 348 may be variable or switched reluctance motors such as those described in U.S. Pat. Nos. 10,348,172 and 9,948,155 and U.S. patent application Ser. No. 14/540,058 titled “Position Feedback for Sealed Environments” filed on Nov. 13, 2014, the disclosures of which are incorporated herein by reference in their entireties. The motors 342, 344, 346, 348 may be harmonic drives such as those described in U.S. Pat. No. 9,656,386 the disclosure of which is incorporated herein by reference in its entirety. Where the robot assembly 10 is used in a sealed environment, such as for non-limiting exemplary purposes only, a vacuum environment, sleeves 362 may be located between the rotors 342R, 344R, 346R, 3418R and the stators 342S, 344S, 346S, 348S so that the coaxial drive shaft assembly 300 is located in the sealed environment and the stators are located outside the sealed environment. It should be realized that the sleeves 362 need not be provided if the robot assembly 10 is only intended for use in an atmospheric environment, such as within an atmospheric section of a substrate processing apparatus.

The fourth or inner shaft 301 extends from the bottom or fourth stator 348S and includes the rotor 348R, which is substantially aligned with the stator 348S. The shaft 302 extends from the third stator 346S and includes rotor 346R, which is substantially aligned with the stator 346S. The shaft 303 extends from the second stator 344S and includes the rotor 344R, which is substantially aligned with the stator 344S. The shaft 304 extends from the top or first stator 342S and includes rotor 342R, which is substantially aligned with the stator 342S. Various bearings 350-353 are provided about the shafts 301-304 and the housing 310 to allow each shaft 301-304 to be independently rotatable relative to each other and the housing 310. It is noted that each shaft may be provided with a position sensor 371-374. The position sensors 371-374 may be used to provide a signal to any suitable controller, such as controller 170, regarding the rotational position of a respective shaft 301-304 relative to each other and/or relative to the housing 310. The sensors 371-374 may be any suitable sensors, such as for non-limiting exemplary purposes, optical or induction sensors.

Here for example, drive axis R1 drives rotation both the upper arm links L1, L2 as a unit. The drive axis R4 drives rotation of both end effectors E1, E2 (e.g., through pulleys P1A-P1C, P4A-P4B, P5A-P5B). The drive axis R2 drives rotation of the forearm link L2 (through pulleys P2A-P2B), while the drive axis R3 drives rotation of the forearm link L4 ((through pulleys (P3A-P3B).

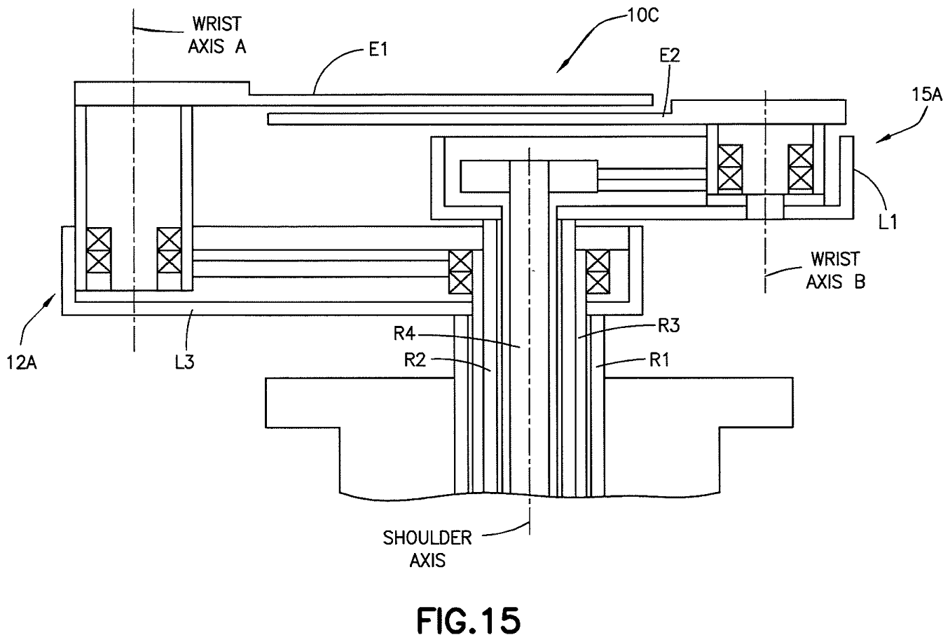

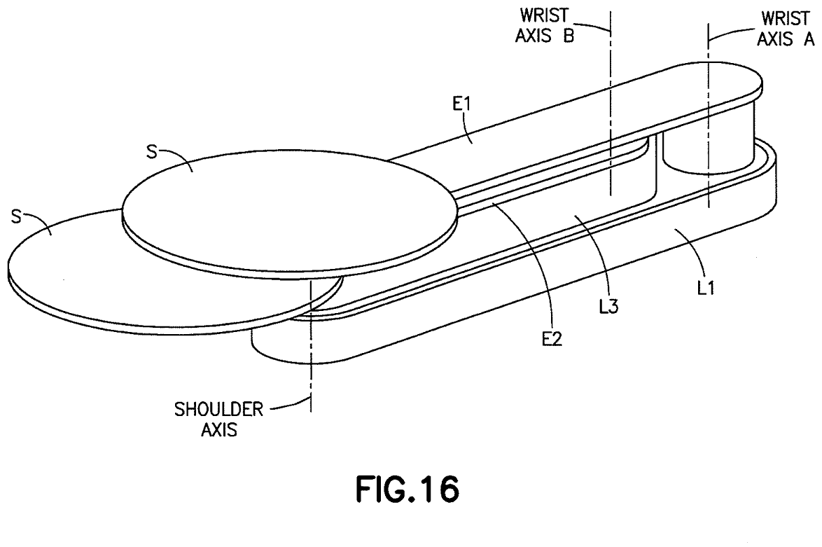

Referring to FIG. 15, a robot assembly 10C is illustrated and is driven by a four-axis drive section such as that described above. Here, the robot assembly 10C includes two arms 12A, 15A, each having an upper arm L1, L3 and at least one end effector E1, E2. The upper arm L1 may be driven in rotation about the shoulder axis by drive axis R2, the upper arm L3 may be driven about the shoulder axis by drive axis R1, end effector E1 may be driven about its wrist axis by drive axis R3, and end effector E2 may be driven about its wrist axis by drive axis R4. Since there is no forearm in robot assembly 10C, the coupling of the end effectors E1, E2 to the respective pulleys/drive shaft will be from, for example, a metal (opposing) band transmission (as described above) between the end effector connection pulley in the respective upper arm L1, L3 at the wrist axis to the main shoulder pulley at the shoulder axis. The end effector E1 is spaced above the upper arm L1 and the end effector E2 is disposed between the upper arm L1 and the end effector E1.

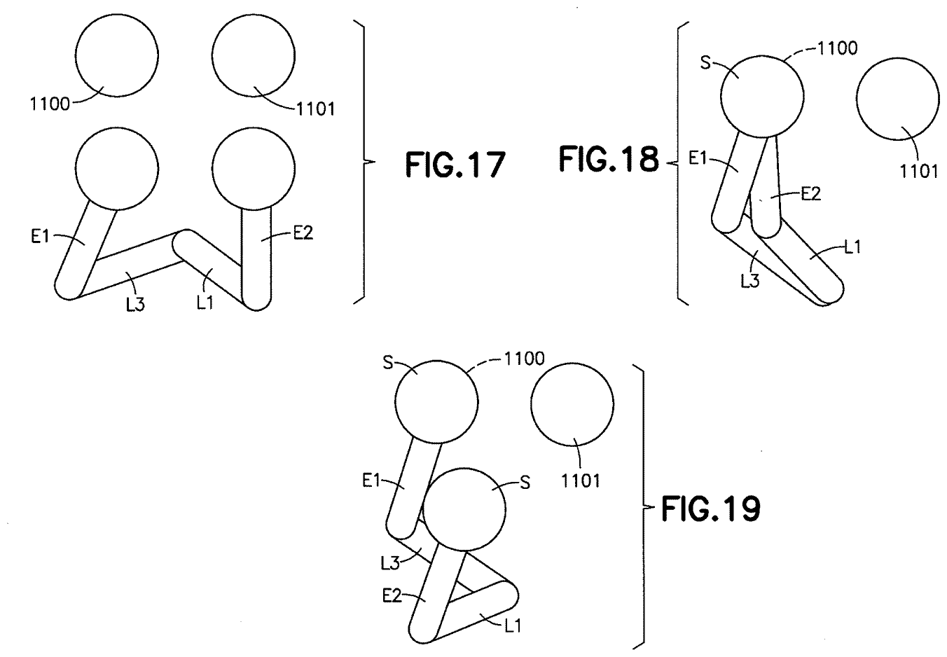

The upper arm L1 may be shorter than the upper arm L3 so that the arms 12A, 15A can pass through each other and offer more flexibility of operation to other station 100, 1101 locations and facilitate a fast swap operation at a specific station as illustrated in FIGS. 17-19. The end effectors E1, E2 can have a “Y” shape in which they can support a trailing substrate S and provide a fast swap operation. The swap function may be effected with the arm links passing each other and switching handedness (again as illustrated in FIGS. 17-19. The robot assembly 10C is capable of performing single substrate S swaps at a particular station 1100, 1101 with the ability to provide substrate transfers to process modules (or any suitable substrate holding stations) on opposing sides at the same time or in a delayed manner due to sharing the same Z-axis. The two arms 12A, 15A effect the robot assembly 10C to service independent process modules (arranged in a manner to holding stations 1100, 1101) located on adjacent facets on a polar coordinate based tool, and/or service adjacent transport chamber sides on a non-radial configured transport chamber (i.e., twin process module) configured Cartesian based tool. This application is another configuration that enables flexibility to extend to each side-by-side process module while also if instructed, have the ability to service stations on other facets.

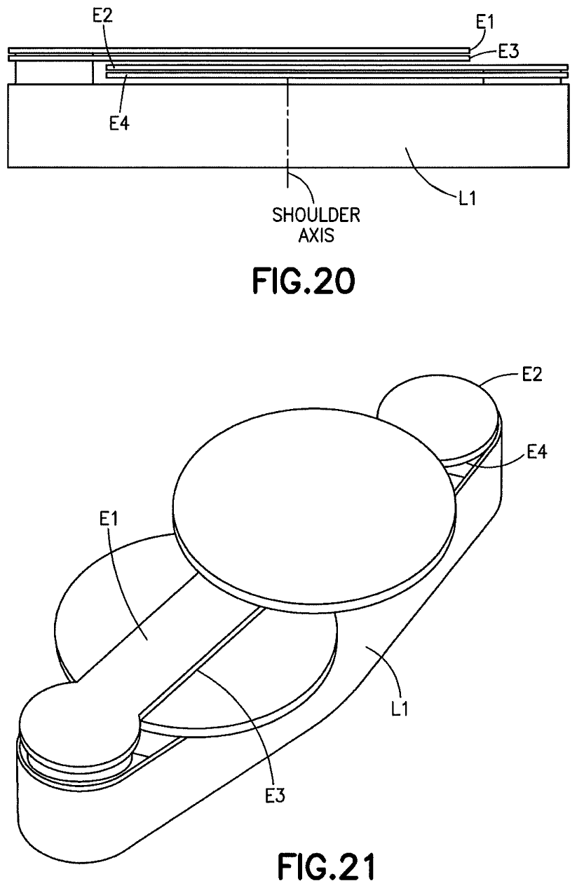

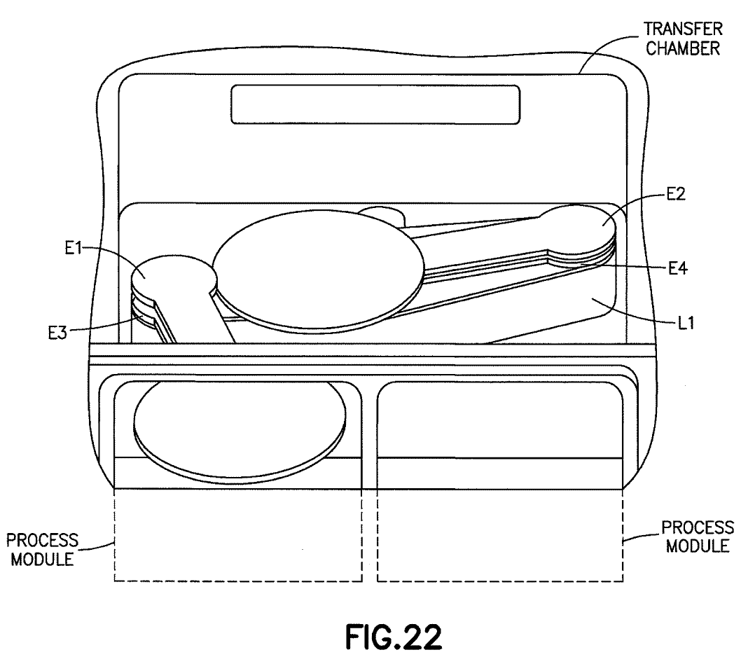

Referring also to FIGS. 20-22, a robot assembly 10D driven by a five-axis drive section (similar to that described above) is illustrated. Here, the robot assembly includes an upper arm L1 that extends on opposite sides of the shoulder axis, where each end of the upper arm L1 has rotatably coupled thereto two end effectors E1-E4. Each end effector E1-E4 and the upper arm L1 are independently drive in rotation about their respective axis of rotation by a respective drive axis R1-R5 of the drive section. The robot assembly of FIGS. 20-22 may allow independent swaps at a process module or any suitable holding station (such as holding stations 1100, 1101). Here, as noted above, the upper arm L1 supports the addition of two more end effectors E1-E4. The end effectors E1-E4 are spaced at 10 mm pitch (although the pitch may be more or less than 10 mm). It is noted that if a sixth axis applied, the present disclosure could be improved in terms of flexibility by allowing all end effectors to be used at each station.

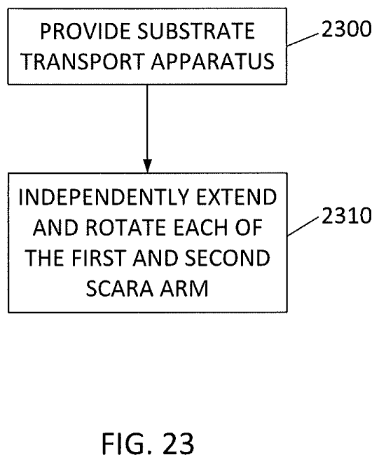

Referring to FIGS. 1-13, 20-22, and 23 an exemplary method of operation of the SCARA transport apparatus 10 will be described in accordance with the present disclosure. The operation may be employed for transporting substrates S. The method includes providing the transport apparatus 10 (FIG. 23, Block 2300), where the transport apparatus 10 includes a frame 16, a first SCARA arm 12, a second SCARA arm 14, and a drive section 220C. The first SCARA arm 12 is coupled to the frame 16 at a shoulder axis of rotation that is fixed relative to the frame 16. The first SCARA arm 12 has a first upper arm L1, a first forearm L2, and at least one substrate holder E1 serially and rotatably coupled to each other. The second SCARA arm 14 is coupled to the frame 16 at the shoulder axis of rotation so that rotation of the first SCARA arm 12 and the second SCARA arm 14 about the shoulder axis of rotation is substantially coincident. The second SCARA arm 14 has a second upper arm L3, a second forearm L4, and at least one substrate holder E2 serially and rotatably coupled to each other. The drive section 220C is connected to the frame 16 and is coupled to the first SCARA arm 12 and the second SCARA arm 14. The drive section 220C is a five motor drive section with five independent motors 342, 343, 344, 346, 348.

The five independent motors 342, 343, 344, 346, 348 of the drive section 220C independently extend and rotate each of the first SCARA arm 12 and the second SCARA arm 14 (FIG. 23, Block 2310), so each of the first SCARA arm 12 and the second SCARA arm 14 extend independently from another of the first SCARA arm 12 and the second SCARA arm 14 and each at least one substrate holder E1, E2 respectively of the first SCARA arm 12 and the second SCARA arm 14 rotates independently of each other at least one substrate holder E1, E2 of the first SCARA arm 12 and the second SCARA arm 14. A first motor 342 of the five independent motors is operably coupled to each first upper arm L1, L3 of both the first SCARA arm 12 and the second SCARA arm 14 so that the first motor 342 is a common motor to both first upper arms L1, L3 respectively of both the first SCARA arm 12 and the second SCARA arm 14.

The method includes one or more of the following, individually or in any suitable combination with each other and/or the features described herein:
independently rotating, with a second independent motor 348 of the five independent motors 342, 343, 344, 346, 348 that is operably coupled to the at least one substrate holder E1 of the first SCARA arm 12, the at least one substrate holder E1 about a first wrist axis T3 of the first SCARA arm 12 independent of each other at least one substrate holder E1, E2 of the first SCARA arm 12 and the second SCARA arm 14;
independently rotating, with a third independent motor 343 of the five independent motors 342, 343, 344, 346, 348 that is operably coupled to the at least one substrate holder E2 of the second SCARA arm 14, the at least one substrate holder E2 about a second wrist axis T5 of the second SCARA arm 14 independent of each other at least one substrate holder E1, E2 of the first SCARA arm 12 and the second SCARA arm 14;
the second independent motor 348 and the third independent motor 343 orientate the at least one substrate holder E1, E2 respectively of the first SCARA arm 12 and the second SCARA arm 14 responsive to a predetermined orientation of a wafer S transported by the at least one substrate holder E1, E2 respectively of the first SCARA arm 12 and the second SCARA arm 14;
the second independent motor 348 and the third independent motor 343 rotate the at least one substrate holder E1, E2 respectively of the first SCARA arm 12 and the second SCARA arm 14 so as to effect a predetermined orientation of a wafer S transported by the at least one substrate holder E1, E2 respectively of the first SCARA arm 12 and the second SCARA arm 14;
independently rotating, with a fourth independent motor 344 of the five independent motors 342, 343, 344, 346, 348 that is operably coupled to the first forearm L2 of the first SCARA arm 12, the first forearm L2 about a first elbow axis T2 of the first SCARA arm 12 independent of each other arm link L1, L3, L4, and the at least one substrate holder E1, E2 of the first SCARA arm 12 and the second SCARA arm 14;
independently rotating, with a fifth independent motor 346 of the five independent motors 342, 343, 344, 346, 348 that is operably coupled to the second forearm L4 of the second SCARA arm 14, the second forearm L4 about a second elbow axis T4 of the second SCARA arm 14 independent of each other arm link L3, L1, L2 and the at least one substrate holder E1, E2 of the first SCARA arm 12 and the second SCARA arm 14;
the second independent motor 348 and the third independent motor 343 orientate the at least one substrate holder E1, E2 respectively of the first SCARA arm 12 and the second SCARA arm 14 responsive to a predetermined orientation of a wafer S transported by another at least one substrate holder of another SCARA arm placing the wafer S for handoff to the first SCARA arm 12 or the second SCARA arm 14;
the drive section 220C comprises a Z-axis drive 312; and
the five independent motors 342, 343, 344, 346, 348 are coaxial.

The following are provided in accordance with the present disclosure and may be employed individually, in any combination with each other, and/or in any combination with the features described above:
In accordance with the present disclosure, a substrate transport apparatus includes: a frame; a first SCARA arm coupled to the frame at a shoulder axis of rotation that is fixed relative to the frame, the first SCARA arm having a first upper arm, a first forearm, and at least one substrate holder serially and rotatably coupled to each other; a second SCARA arm coupled to the frame at the shoulder axis of rotation so that rotation of the first SCARA arm and the second SCARA arm about the shoulder axis of rotation is substantially coincident, the second SCARA arm having a second upper arm, a second forearm, and at least one substrate holder serially and rotatably coupled to each other; and a drive section connected to the frame and coupled to the first SCARA arm and the second SCARA arm, the drive section being a five motor drive section with five independent motors configured to independently extend and rotate each of the first SCARA arm and the second SCARA arm so each of the first SCARA arm and the second SCARA arm extend independently from another of the first SCARA arm and the second SCARA arm and each at least one substrate holder respectively of the first SCARA arm and the second SCARA arm rotates independently of each other at least one substrate holder of the first SCARA arm and the second SCARA arm; wherein a first motor of the five independent motors is operably coupled to each first upper arm of both the first SCARA arm and the second SCARA arm so that the first motor is a common motor to both first upper arms respectively of both the first SCARA arm and the second SCARA arm.

In accordance with the present disclosure, the substrate transport apparatus includes one or more of, individually, or in any suitable combination thereof:
a second independent motor of the five independent motors, is operably coupled to the at least one substrate holder of the first SCARA arm, so as to independently rotate the at least one substrate holder about a first wrist axis of the first SCARA arm independent of each other at least one substrate holder of the first SCARA arm and the second SCARA arm;
a third independent motor of the five independent motors, is operably coupled to the at least one substrate holder of the second SCARA arm, so as to independently rotate the at least one substrate holder about a second wrist axis of the second SCARA arm independent of each other at least one substrate holder of the first SCARA arm and the second SCARA arm;
the second independent motor and the third independent motor orientate the at least one substrate holder respectively of the first SCARA arm and the second SCARA arm responsive to a predetermined orientation of a wafer transported by the at least one substrate holder respectively of the first SCARA arm and the second SCARA arm;
the second independent motor and the third independent motor rotate the at least one substrate holder respectively of the first SCARA arm and the second SCARA arm so as to effect a predetermined orientation of a wafer transported by the at least one substrate holder respectively of the first SCARA arm and the second SCARA arm;
a fourth independent motor of the five independent motors, is operably coupled to the first forearm of the first SCARA arm, so as to independently rotate the first forearm about a first elbow axis of the first SCARA arm independent of each other arm link and the at least one substrate holder of the first SCARA arm and the second SCARA arm;
a fifth independent motor of the five independent motors, is operably coupled to the second forearm of the second SCARA arm, so as to independently rotate the second forearm about a second elbow axis of the second SCARA arm independent of each other arm link and the at least one substrate holder of the first SCARA arm and the second SCARA arm;
the second independent motor and the third independent motor orientate the at least one substrate holder respectively of the first SCARA arm and the second SCARA arm responsive to a predetermined orientation of a wafer transported by another at least one substrate holder of another SCARA arm placing the wafer for handoff to the first SCARA arm or the second SCARA arm;
the drive section comprises a z-axis drive; and
the five independent motors are coaxial.

In accordance with the present disclosure, a method includes: providing a substrate transport apparatus that includes: a frame; a first SCARA arm coupled to the frame at a shoulder axis of rotation that is fixed relative to the frame, the first SCARA arm having a first upper arm, a first forearm, and at least one substrate holder serially and rotatably coupled to each other; a second SCARA arm coupled to the frame at the shoulder axis of rotation so that rotation of the first SCARA arm and the second SCARA arm about the shoulder axis of rotation is substantially coincident, the second SCARA arm having a second upper arm, a second forearm, and at least one substrate holder serially and rotatably coupled to each other; and a drive section connected to the frame and coupled to the first SCARA arm and the second SCARA arm, the drive section being a five motor drive section with five independent motors; independently extending and rotating each of the first SCARA arm and the second SCARA arm, with the five independent motors of the drive section, so each of the first SCARA arm and the second SCARA arm extend independently from another of the first SCARA arm and the second SCARA arm and each at least one substrate holder respectively of the first SCARA arm and the second SCARA arm rotates independently of each other at least one substrate holder of the first SCARA arm and the second SCARA arm; wherein a first motor of the five independent motors is operably coupled to each first upper arm of both the first SCARA arm and the second SCARA arm so that the first motor is a common motor to both first upper arms respectively of both the first SCARA arm and the second SCARA arm.

In accordance with the present disclosure, the method includes one or more of, individually, or in any suitable combination thereof:
independently rotating, with a second independent motor of the five independent motors that is operably coupled to the at least one substrate holder of the first SCARA arm, the at least one substrate holder about a first wrist axis of the first SCARA arm independent of each other at least one substrate holder of the first SCARA arm and the second SCARA arm;
independently rotating, with a third independent motor of the five independent motors that is operably coupled to the at least one substrate holder of the second SCARA arm, the at least one substrate holder about a second wrist axis of the second SCARA arm independent of each other at least one substrate holder of the first SCARA arm and the second SCARA arm;
the second independent motor and the third independent motor orientate the at least one substrate holder respectively of the first SCARA arm and the second SCARA arm responsive to a predetermined orientation of a wafer transported by the at least one substrate holder respectively of the first SCARA arm and the second SCARA arm;
the second independent motor and the third independent motor rotate the at least one substrate holder respectively of the first SCARA arm and the second SCARA arm so as to effect a predetermined orientation of a wafer transported by the at least one substrate holder respectively of the first SCARA arm and the second SCARA arm;
independently rotating, with a fourth independent motor of the five independent motors that is operably coupled to the first forearm of the first SCARA arm, the first forearm about a first elbow axis of the first SCARA arm independent of each other arm link and the at least one substrate holder of the first SCARA arm and the second SCARA arm;
independently rotating, with a fifth independent motor of the five independent motors that is operably coupled to the second forearm of the second SCARA arm, the second forearm about a second elbow axis of the second SCARA arm independent of each other arm link and the at least one substrate holder of the first SCARA arm and the second SCARA arm;
the second independent motor and the third independent motor orientate the at least one substrate holder respectively of the first SCARA arm and the second SCARA arm responsive to a predetermined orientation of a wafer transported by another at least one substrate holder of another SCARA arm placing the wafer for handoff to the first SCARA arm or the second SCARA arm;
the drive section comprises a Z-axis drive; and
the five independent motors are coaxial.

It should be understood that the foregoing description is only illustrative of the present disclosure. Various alternatives and modifications can be devised by those skilled in the art without departing from the present disclosure. Accordingly, the present disclosure is intended to embrace all such alternatives, modifications and variances that fall within the scope of any claims appended hereto. Further, the mere fact that different features are recited in mutually different dependent or independent claims does not indicate that a combination of these features cannot be advantageously used, such a combination remaining within the scope of the present disclosure.

What is claimed is:

1. A substrate transport apparatus comprising:
a frame;
a first SCARA arm coupled to the frame at a shoulder axis of rotation that is fixed relative to the frame, the first SCARA arm having a first upper arm, a first forearm, and at least one substrate holder serially and rotatably coupled to each other;
a second SCARA arm coupled to the frame at the shoulder axis of rotation so that rotation of the first SCARA arm and the second SCARA arm about the shoulder axis of rotation is substantially coincident, the second SCARA arm having a second upper arm, a second forearm, and at least one substrate holder serially and rotatably coupled to each other; and
a drive section connected to the frame and coupled to the first SCARA arm and the second SCARA arm, the drive section being a five motor drive section with five independent motors configured to independently extend and rotate each of the first SCARA arm and the second SCARA arm so each of the first SCARA arm and the second SCARA arm extend independently from another of the first SCARA arm and the second SCARA arm and each at least one substrate holder respectively of the first SCARA arm and the second SCARA arm rotates independently of each other at least one substrate holder of the first SCARA arm and the second SCARA arm;
wherein a first motor of the five independent motors is operably coupled to each first upper arm of both the first SCARA arm and the second SCARA arm so that the first motor is a common motor to both first upper arms respectively of both the first SCARA arm and the second SCARA arm.

2. The substrate transport apparatus of claim 1, wherein a second independent motor of the five independent motors, is operably coupled to the at least one substrate holder of the first SCARA arm, so as to independently rotate the at least one substrate holder about a first wrist axis of the first SCARA arm independent of each other at least one substrate holder of the first SCARA arm and the second SCARA arm.

3. The substrate transport apparatus of claim 2, wherein a third independent motor of the five independent motors, is operably coupled to the at least one substrate holder of the second SCARA arm, so as to independently rotate the at least one substrate holder about a second wrist axis of the second SCARA arm independent of each other at least one substrate holder of the first SCARA arm and the second SCARA arm.

4. The substrate transport apparatus of claim 3, wherein the second independent motor and the third independent motor orientate the at least one substrate holder respectively of the first SCARA arm and the second SCARA arm responsive to a predetermined orientation of a wafer transported by the at least one substrate holder respectively of the first SCARA arm and the second SCARA arm.

5. The substrate transport apparatus of claim 3, wherein the second independent motor and the third independent motor rotate the at least one substrate holder respectively of the first SCARA arm and the second SCARA arm so as to effect a predetermined orientation of a wafer transported by the at least one substrate holder respectively of the first SCARA arm and the second SCARA arm.

6. The substrate transport apparatus of claim 3, wherein a fourth independent motor of the five independent motors, is operably coupled to the first forearm of the first SCARA arm, so as to independently rotate the first forearm about a first elbow axis of the first SCARA arm independent of each other arm link and the at least one substrate holder of the first SCARA arm and the second SCARA arm.

7. The substrate transport apparatus of claim 6, wherein a fifth independent motor of the five independent motors, is operably coupled to the second forearm of the second SCARA arm, so as to independently rotate the second forearm about a second elbow axis of the second SCARA arm independent of each other arm link and the at least one substrate holder of the first SCARA arm and the second SCARA arm.

8. The substrate transport apparatus of claim 3, wherein the second independent motor and the third independent motor orientate the at least one substrate holder respectively of the first SCARA arm and the second SCARA arm responsive to a predetermined orientation of a wafer transported by another at least one substrate holder of another SCARA arm placing the wafer for handoff to the first SCARA arm or the second SCARA arm.

9. The substrate transport apparatus of claim 1, wherein the drive section comprises a Z-axis drive.

10. The substrate transport apparatus of claim 1, wherein the five independent motors are coaxial.

11. A method comprising:
providing a substrate transport apparatus that includes:
a frame;
a first SCARA arm coupled to the frame at a shoulder axis of rotation that is fixed relative to the frame, the first SCARA arm having a first upper arm, a first forearm, and at least one substrate holder serially and rotatably coupled to each other;
a second SCARA arm coupled to the frame at the shoulder axis of rotation so that rotation of the first SCARA arm and the second SCARA arm about the shoulder axis of rotation is substantially coincident, the second SCARA arm having a second upper arm, a second forearm, and at least one substrate holder serially and rotatably coupled to each other; and
a drive section connected to the frame and coupled to the first SCARA arm and the second SCARA arm, the drive section being a five motor drive section with five independent motors;
independently extending and rotating each of the first SCARA arm and the second SCARA arm, with the five independent motors of the drive section, so each of the first SCARA arm and the second SCARA arm extend independently from another of the first SCARA arm and the second SCARA arm and each at least one substrate holder respectively of the first SCARA arm and the second SCARA arm rotates independently of each other at least one substrate holder of the first SCARA arm and the second SCARA arm;
wherein a first motor of the five independent motors is operably coupled to each first upper arm of both the first SCARA arm and the second SCARA arm so that the first motor is a common motor to both first upper arms respectively of both the first SCARA arm and the second SCARA arm.

12. The method of claim 11, further comprising independently rotating, with a second independent motor of the five independent motors that is operably coupled to the at least one substrate holder of the first SCARA arm, the at least one substrate holder about a first wrist axis of the first SCARA arm independent of each other at least one substrate holder of the first SCARA arm and the second SCARA arm.

13. The method of claim 12, further comprising independently rotating, with a third independent motor of the five independent motors that is operably coupled to the at least one substrate holder of the second SCARA arm, the at least one substrate holder about a second wrist axis of the second SCARA arm independent of each other at least one substrate holder of the first SCARA arm and the second SCARA arm.

14. The method of claim 13, wherein the second independent motor and the third independent motor orientate the at least one substrate holder respectively of the first SCARA arm and the second SCARA arm responsive to a predetermined orientation of a wafer transported by the at least one substrate holder respectively of the first SCARA arm and the second SCARA arm.

15. The method of claim 13, wherein the second independent motor and the third independent motor rotate the at least one substrate holder respectively of the first SCARA arm and the second SCARA arm so as to effect a predetermined orientation of a wafer transported by the at least one substrate holder respectively of the first SCARA arm and the second SCARA arm.

16. The method of claim 13, further comprising independently rotating, with a fourth independent motor of the five independent motors that is operably coupled to the first forearm of the first SCARA arm, the first forearm about a first elbow axis of the first SCARA arm independent of each other arm link and the at least one substrate holder of the first SCARA arm and the second SCARA arm.

17. The method of claim 16, further comprising independently rotating, with a fifth independent motor of the five independent motors that is operably coupled to the second forearm of the second SCARA arm, the second forearm about a second elbow axis of the second SCARA arm independent of each other arm link and the at least one substrate holder of the first SCARA arm and the second SCARA arm.

18. The method of claim 13, wherein the second independent motor and the third independent motor orientate the at least one substrate holder respectively of the first SCARA arm and the second SCARA arm responsive to a predetermined orientation of a wafer transported by another at least one substrate holder of another SCARA arm placing the wafer for handoff to the first SCARA arm or the second SCARA arm.

19. The method of claim 11, wherein the drive section comprises a Z-axis drive.

20. The method of claim 11, wherein the five independent motors are coaxial.
